(19) United States
(12) Patent Application Publication
(10) Pub. No.: US 2024/0373110 A1
(43) Pub. Date: Nov. 7, 2024

(54) DETECTOR MODULE, OPTOELECTRONIC IMAGE CAPTURE SYSTEM AND AIRCRAFT FOR IMAGE CAPTURE

(71) Applicant: Jena-Optronik GmbH, Jena (DE)

(72) Inventors: Andreas ZINTL, Arnstadt (DE); Steffen RIENECKER, Ballenstedt (DE); Christian KERL, Jena (DE); Mathias STELLMACH, Posterstein (DE); Hans-Ulrich ZÜHLKE, Jena (DE)

(73) Assignee: Jena-Optronik GmbH, Jena (DE)

(21) Appl. No.: 18/683,704

(22) PCT Filed: Aug. 19, 2022
(86) PCT No.: PCT/EP2022/073199

§ 371 Date: Feb. 14, 2024

(30) Foreign Application Priority Data
Aug. 20, 2021 (DE) 10 2021 121 609.5

(51) Int. Cl. H04N 23/52; B64G 1/66; G03B 15/00; G03B 30/00; H04N 23/54; H04N 23/90

(52) U.S. Cl. CPC H04N 23/52; B64G 1/66; G03B 15/006; G03B 30/00; H04N 23/54; H04N 23/90

(57) ABSTRACT

A detector module for image capture, in particular for an optoelectronic image capture system for an aircraft, such as a spacecraft, comprising a main module body and at least one optoelectronic element arranged on and/or integrated in the main module body, wherein the at least one optoelectronic element has at least one line with a multiplicity of pixels, such as pixel line, and an optoelectronic image capture system and aircraft, such as spacecraft.

### CROSS-REFERENCE TO RELATED APPLICATION

This application is a 35 U.S.C. § 371 national phase entry of PCT Application No. PCT/EP2022/073199, filed on Aug. 19, 2022, which claims priority to German Patent Application No. 10 2021 121 609.5, filed on Aug. 20, 2021, the entire contents of both are hereby incorporated by reference.

### DESCRIPTION

The disclosure relates to a detector module for image capture, particularly for an optoelectronic image capture system for an aircraft, such as a spacecraft. The disclosure also relates to at least one optoelectronic image capture system having a detector module and a corresponding aircraft, such as a spacecraft.

Optoelectronic imaging systems are used, for example, in the area of space travel for earth observation. Typically, such imaging systems have optics, one or more detectors in an image plane and electronics. The combination of several detectors is necessary for high-resolution earth observation. The detectors are usually designed as a line with a corresponding resolution. Depending on the application, several detector lines, also known as sensor lines, can also be combined with one another in order to be able to record a larger area, for example with a larger swath width. It is necessary for the detectors to overlap in the edge area. Several line detectors or optoelectronic elements, such as line elements, can therefore be arranged as an array in the image field or on the image plane or focal plane (“focal plane assembly”, FPA). With high-resolution sensors/detectors, different spectral ranges are usually examined or used. Each detector line, for example consisting of overlapping detectors or optoelectronic elements, can be optimized for a separate spectral range.

The familiar FPA solutions in a planar arrangement and with a monolithic FPA base plate and sensors assembled on it in separate housings or chip carriers cannot be optimally adapted to the new generation of much larger sensors. The new sensors may have more and/or smaller pixels and/or a significantly higher integration density due to substantially more functions on the chip, and/or higher clock rates and/or potentially higher power dissipation. Electrical connections to peripheral components must be short and of high electrical quality. However, there is no space for the peripheral components in the direction of the image plane. Apertures in the FPA base plate for electronic components perpendicular to the image plane can worsen the thermal behavior due to inhomogeneity. These apertures can also be difficult to produce and can worsen the mechanical-thermal properties of the monolithic base plate. The high data rate of the new sensors can require communication with a very high bandwidth. This can be realized by optical links. The arrangement of the optical link can also be difficult on the plane. Both the routing of the optical fibers and/or the placement of the optical link close to the data source (necessary due to the high clock rates) and the thermal management can lead to larger space requirements.

The sensors can currently be glued and/or non-detachably fastened for precise fixation after adjustment and/or for good thermal fastening. If a sensor fails, the totality of the monolithic FPA must be replaced.

The sensors and peripheral components (e.g. clock drivers) can form thermal hotspots that cannot be selectively compensated for in a monolithic FPA. For the sensor, the occurrence of temperature gradients means a deterioration of the operating point. The possible optical resolution with the new generation of sensors can also only be utilized if thermal expansion effects can be avoided as far as possible, which in turn can be difficult in a monolithic, planar FPA.

Sensors with a higher resolution also require a more precise adjustment to one another. However, adjustment tools can only be used to a limited extent in a planar FPA with the desired minimum distances between the sensors due to the spatial confinement.

A planar monolithic FPA further requires high-quality optics, which must ensure a flat image field and color error-free imaging. It can be difficult to adapt the planar FPA to special features of the image, such as image field curvature and/or color error correction.

The object of embodiments is to structurally and/or functionally improve a detector module mentioned at the beginning. Furthermore, the object of embodiments is to structurally and/or functionally improve an optoelectronic image capture system mentioned at the beginning. Furthermore, the object of embodiments is to structurally and/or functionally improve an aircraft, such as a spacecraft, for image capture.

The object of embodiments is particularly to avoid the described disadvantages of a planar and/or monolithic FPA, for example to enable effective packaging or a more compact and improved arrangement of optoelectronic detectors in the FPA. A further object of embodiments is to increase the integration density, particularly in the image field or on the image plane or focal plane, and to improve performance.

The object is achieved with a detector module having the features of claim 1. Furthermore, the object is achieved with an optoelectronic image capture system having the features of claim 34. Furthermore, the object is achieved with an aircraft, such as a spacecraft, having the features of claim 41. Advantageous embodiments and/or further embodiments are the subject matter of the subclaims, the description and/or the accompanying figures. In particular, the independent claims of one category of claims may also be further defined analogously to the dependent claims of another category of claims.

The detector module can be used and/or designed for image capture. The detector module can be for and/or arranged in an optoelectronic image capture system. The detector module can be for and/or arranged on an aircraft, for example a spacecraft. The detector module can be or be designed for earth observation, particularly for high-resolution earth observation.

The detector module may comprise a main module body. The detector module can comprise at least one optoelectronic element, for example a detector and/or light-sensitive sensor chip, arranged and/or integrated on the main module body, for example directly. The at least one optoelectronic element may have at least one line with a plurality of pixels, such as pixel lines.

The detector module can have several optoelectronic elements, for example detectors and/or light-sensitive sensor chips, arranged on and/or integrated into the main module body, for example directly. The multiple optoelectronic elements can be arranged substantially in series in one direction, such as the longitudinal direction of the detector module and/or the main module body. The longitudinal direction can be a longitudinal direction of the detector module and/or the main module body. The longitudinal direction can substantially be the direction of the longitudinal axis and/or substantially the direction of the longest extension of the detector module and/or the main module body. The plurality of optoelectronic elements, for example arranged one behind the other, can overlap in portions, for example in one direction, such as the longitudinal direction of the detector module and/or the main module body, and/or in their end areas, particularly when viewed in the transverse direction. The lines with a plurality of pixels, such as pixel lines, of the plurality of optoelectronic elements arranged, for example, one behind the other, can overlap in portions, in particular in one direction, such as the longitudinal direction of the detector module or main module body, and/or in their end areas, particularly when viewed in the transverse direction. The transverse direction can be a lateral direction of the detector module and/or the main module body. The transverse direction can substantially be the direction of the transverse axis of the detector module or main module body and/or substantially the direction transverse, such as perpendicular, to the longitudinal direction. The transverse direction can further substantially be the direction of a shorter and/or the shortest extension of the detector module and/or the main module body. The transverse direction or transverse axis and the longitudinal direction or longitudinal axis can lie in one plane. The plane can be defined and/or designed by a carrier surface, particularly of the main module body. The plane can be parallel to the carrier surface.

The plurality of optoelectronic elements, for example arranged one behind the other, can be arranged directly adjacent to or spaced apart from one another, for example in a direction such as the longitudinal direction of the detector module or main module body. The plurality of optoelectronic elements, for example arranged one behind the other, can be arranged at a distance, for example in one direction, such as the longitudinal direction of the detector module or main module body.

The detector module and/or the at least one optoelectronic element can be designed for at least one spectral channel and/or color channel. The detector module and/or the at least one optoelectronic element can be designed and/or optimized for at least one spectral range.

The at least one optoelectronic element can be connected to the main module body. For example, the at least one optoelectronic element can be firmly connected to the main module body, such as bonded and/or non-detachably connected.

The at least one optoelectronic element can be a light-sensitive chip. The at least one optoelectronic element can be a CMOS chip and/or have at least one active pixel technology. The at least one optoelectronic element may be and/or comprise a CCD chip, a photodiode or similar.

The at least one optoelectronic element may have at least one printed circuit board. The at least one printed circuit board can be designed to be rigid or flexible, at least in portions. The at least one printed circuit board can be a rigid or flexible printed circuit board. The at least one optoelectronic element may comprise at least one integrated signal processing and/or readout circuit. The at least one optoelectronic element may comprise at least one line-shaped light-sensitive chip. The at least one light-sensitive chip can be a CMOS chip, a CCD chip, a photodiode or similar. The at least one optoelectronic element can have, particularly in its longitudinal direction, at least one line, such as a pixel line, with a plurality of pixels. The at least one optoelectronic element can have, for example, between 1000 and 30000 pixels, particularly between 5000 and 25000 pixels, in embodiments approx. 10000 or approx. 20000 pixels as a pixel line. The at least one optoelectronic element can have a number of sub-lines, such as sub-pixel lines, arranged parallel to one another, particularly in its transverse direction/lateral direction, each with a plurality of pixels. The at least one optoelectronic element can, for example, have a number of sublines corresponding to a power of 2, particularly up to 512 or 1024. The pixel line can have a plurality of sub-pixel lines.

The at least one optoelectronic element can be and/or comprise a sensor and/or detector and/or a light-sensitive electronic chip and/or a light-sensitive sensor chip. The at least one optoelectronic element can be an optoelectronic detector and/or a light-sensitive sensor chip. The at least one optoelectronic element can be integrated directly in the detector module and/or directly on or in the main module body.

The main module body can be designed in several parts. For example, the main module body can be designed in two, three, four or five parts. At least one part or each part of the main module body may have at least one optoelectronic element.

The main module body can, for example in the longitudinal direction and/or in the transverse direction of the main module body, be designed substantially arcuate and/or wedge-shaped and/or angled and/or stepped, at least in portions. Step-shaped can also be understood as stair-shaped. The main module body can have a central portion and at least one portion that is angled or stepped towards the central portion. At least one or each portion of the main module body may have at least one optoelectronic element. The main module body can be designed substantially wedge-shaped and/or curved and/or angled and/or stepped in a direction transverse to an image field or an image plane and/or to a longitudinal extension of the at least one optoelectronic element.

The at least one optoelectronic element can, for example in the longitudinal direction and/or in the transverse direction of the at least one optoelectronic element, be designed substantially wedge-shaped and/or step-shaped and/or angled and/or curved, for example curved, at least in portions. The detector module, in particular the at least one or the optoelectronic elements of the detector module, can have and/or form a substantially planar, concave, convex or spherical, for example common, image field and/or, for example common, focal surface.

The main module body can be designed substantially U-shaped or T-shaped. The main module body can have at least one carrier surface. The at least one optoelectronic element and/or the multiple optoelectronic elements can be arranged on the carrier surface. The at least one optoelectronic element and/or the multiple optoelectronic elements can be integrated directly in the main module body and/or in the carrier surface and/or can be fixedly arranged thereon. The main module body can have at least one portion designed substantially perpendicular to the carrier surface, which can be designed to accommodate at least one electronic circuit and/or electronics, such as a signal processing and/or readout circuit, and/or to accommodate at least one printed circuit board. The at least one electronic circuit and/or electronics and/or printed circuit board can be connected, particularly electrically, to the at least one optoelectronic element. The at least one portion can have at least one receiving area, for example a recess, cut-out and/or pocket, in which the at least one electronic circuit and/or electronics and/or printed circuit board can be arranged and/or disposed. The at least one electronic circuit and/or electronics and/or printed circuit board can be arranged and/or arranged transversely, for example perpendicularly, to the carrier surface.

The detector module may have the at least one electronic circuit and/or electronics and/or printed circuit board, which may be connected, particularly electrically, to the at least one optoelectronic element. The at least one electronic circuit and/or electronics and/or printed circuit board may be arrangeable and/or arranged at an angle, for example transversely and/or substantially perpendicularly, to the carrier surface and/or to the at least one optoelectronic element.

The at least one electronic circuit and/or electronics and/or printed circuit board can be electrically connected to the at least one optoelectronic element. The at least one electronic circuit and/or electronics and/or printed circuit board can be electrically connected to the at least one optoelectronic element by means of bonding, for example wire ground, or a bond connection. Additionally or alternatively, the at least one electronic circuit and/or electronics and/or printed circuit board may be electrically connected to the at least one optoelectronic element by means of soldering, such as solder jet bumping or laser soldering, or a solder connection. Additionally or alternatively, the at least one electronic circuit and/or electronics and/or printed circuit board may be electrically connected to the at least one optoelectronic element by means of welding, such as laser welding, or a welding connection. The electrical connection can be made or realized via a face side and/or side surface of the at least one printed circuit board. One face side of the at least one printed circuit board can have at least one electrically conductive contact point. The at least one electrically conductive contact point of the face side of the at least one printed circuit board can be electrically connected to at least one electrically conductive contact point of the at least one optoelectronic element. The at least one printed circuit board may have conductive tracks extending transversely and/or substantially perpendicular to one another. At least one conductive track of the at least one printed circuit board can extend substantially parallel to a face side of the at least one printed circuit board. At least one further conductive track of the at least one printed circuit board can extend substantially parallel to a side surface of the at least one printed circuit board that extends substantially perpendicular to the face side. At least one further printed circuit board aligned substantially perpendicular to the printed circuit board can be arranged on one face side of the at least one printed circuit board. The at least one further printed circuit board can be electrically connected to the at least one optoelectronic element, for example via an electrically conductive contact point. The at least one printed circuit board can be electrically connected to the at least one further printed circuit board, for example by means of bonding, such as wire bonding, and/or by means of soldering, such as solder jet bumping, and/or by means of welding, such as laser welding. The at least one printed circuit board and/or the at least one further printed circuit board can form a segmented printed circuit board with the at least one printed circuit board of the at least one optoelectronic element. The printed circuit boards can, for example, be produced as PCBs (printed circuit boards), by means of LTCCs (low temperature cofired ceramics), HTCCs (high temperature cofired ceramics) or based on glass. The electrically conductive contact points can be so-called pads. The conductive tracks can be flat layers/tracks, for example, made of metal. Space-saving contacting from the vertical circuit board directly to the chip/optoelectronic element can therefore be realized.

The detector module may have at least one cooling apparatus and/or heating apparatus. The cooling apparatus and/or heating apparatus can be arranged and/or designed on the main module body. The cooling apparatus and/or heating apparatus can be designed to cool and/or heat the at least one optoelectronic element. The main module body can be designed to form a graduated temperature distribution. The main module body can have different wall thicknesses and/or material thicknesses, for example to form a graduated temperature distribution. The main module body can be produced, particularly to form different temperature distributions, at least in portions from materials that have different thermal conductivities and/or thermal conductivity coefficients. Additionally or alternatively, at least one air gap can be provided, particularly to influence the heat conduction function and/or temperature distributions. The main module body can be designed for targeted cooling and/or heating. The detector module and/or the main module body can have at least one cooling line and/or heat conduction, for example for targeted cooling and/or heating. The at least one cooling apparatus and/or heating apparatus and/or the at least one cooling line and/or heat line can be designed to transport and/or supply and discharge cooling means and/or heating means. The cooling means or heating means can be a particularly flowing Cooling or heating medium, for example a fluid such as a liquid or gas. The at least one cooling apparatus and/or heating apparatus and/or the at least one cooling line and/or heating line can be designed to supply the cooling means or heating means in liquid form and, particularly due to evaporation, to discharge it in vaporous and/or gaseous form. In addition or alternatively, the at least one cooling apparatus and/or heating apparatus and/or the at least one cooling line and/or heat line can be designed to supply the cooling means or heating means in vaporous and/or gaseous form and to discharge it in liquid form, for example due to cooling.

The at least one cooling apparatus and/or heating apparatus and/or the at least one cooling line and/or heating line can be designed to supply cooling means or heating means to one side of the detector module and to discharge them from a side of the detector module opposite this side. The at least one cooling apparatus and/or heating apparatus and/or the at least one cooling line and/or heating line can be designed to supply cooling means or heating means at a substantially internal and/or central location of the detector module and to discharge them at a side, such as the exterior side, of the detector module. The at least one cooling line and/or heating line can be designed to influence and/or change the flow properties of a cooling means and/or heating means, for example by means of adapted cross-sections, such as line cross-sections. The at least one cooling line or heating line can have the same cross-section throughout or different cross-sections at least in sections. The cross-sections can be round, such as circular, or angular. The cross-sections can define and/or have a diameter. The at least one cooling line or heating line can be designed accordingly to form different flow speeds. The at least one cooling line and/or heating line may have a larger cross-section on one side of the detector module than on a side of the detector module opposite this side. The at least one cooling line and/or heating line can have a larger or smaller cross-section on a supply side/supply point of the detector module than on a discharge side/discharge point of the detector module. The cross-section can be a cable cross-section. The at least one cooling line and/or heating line can taper conically in the direction of flow or against the direction of flow of the cooling means and/or heating means, at least in portions. Additionally or alternatively, the cooling line and/or heating line may have several conduits, for example several lines designed as strands. Several strands/lines can form strand or line packs. The multiple strands/lines, for example of a strand or line bundle, can have the same cross-sections or different cross-sections. Strand packs can be provided, wherein several strands of the same cross-section can be bundled to fit. Each detector module can have an individual cooling and/or heating apparatus or individual cooling and/or heating circuits.

An optoelectronic image capture system can be for an aircraft, such as a spacecraft. The optoelectronic image capture system can be designed for earth observation, particularly for high-resolution earth observation. The optoelectronic image capture system can have a modular image field arrangement or image plane arrangement and/or focal plane arrangement/focal area arrangement. The optoelectronic image capture system can have at least one detector module or several detector modules. The at least one detector module or the plurality of detector modules may be designed as described above and/or below.

The multiple detector modules, particularly the optoelectronic elements of the detector modules, can form and/or define a common image field/image plane and/or common focal area/focal plane. The multiple detector modules can be arranged next to one another and/or parallel to one another and/or connected to one another, for example directly and/or longitudinally. The multiple detector modules can be arranged along a straight or curved line. The line can extend substantially transversely, for example perpendicularly, to the longitudinal direction of the detector module(s) and/or main module body. The multiple detector modules can be arranged and/or lined up substantially in an arc. The common image field/image plane and/or focal surface/focal plane can be substantially curved, for example convex or concave or spherically curved, for example in the image capture direction and/or flight direction and/or longitudinal direction of the aircraft, such as a spacecraft, and/or in the lateral direction or transverse, such as substantially perpendicular, to the image capture direction and/or flight direction of the aircraft, such as a spacecraft.

The optoelectronic image capture system can have optics focusing on at least one detector module, particularly on at least one optoelectronic element, and/or on the image field/image plane and/or on the focal surface/focal plane. The at least one detector module or the multiple detector modules or the carrier surfaces of the main module bodies can be arranged within an imaging area of the optics in the image field/image plane. The optics can be designed to focus on a single detector module or on several detector modules and/or on a single optoelectronic element and/or on several optoelectronic elements, for example simultaneously or in succession. The optics can, for example, be designed as an objective or have an objective. The optics can, for example, be designed as a telescope or have a telescope. The optics may have one or more lenses and/or mirrors. The optics may have a tube. One or more lenses and/or mirrors can be arranged in the tube. The optics may have a motor, such as a stepper motor, for adjusting one or more lenses and/or mirrors.

An aircraft, such as a spacecraft, can have at least one detector module or a plurality of detector modules. The at least one detector module or the plurality of detector modules may be designed as described above and/or below. An aircraft, such as a spacecraft, may have at least one optoelectronic image capture system. The at least one optoelectronic image capture system may be designed as described above and/or below. The aircraft can be a spacecraft. The aircraft can be for earth observation, particularly for high-resolution earth observation. The aircraft can be a drone, an aircraft, a satellite, particularly an artificial satellite, for example an earth satellite, a space probe, for example an orbiter, a rocket, a space shuttle, a spaceship, a spacecraft, a space capsule, a space station or similar. The aircraft, particularly spacecraft, may be designed to move in space or to be taken there. The aircraft or spacecraft can be a deep space missile. The aircraft or spacecraft can be designed to be placed in an earth orbit and/or to move and/or hover in an earth orbit. The aircraft or spacecraft may be designed to travel and/or hover at an altitude of, for example, approximately 100 m, 10 km and/or 1000 km or more. The aircraft or spacecraft can be designed to be brought into an orbit of a planet and/or celestial body and/or to move and/or hover in a circular path of the planet or celestial body. The celestial body can, for example, be a planet, star, moon, asteroid, etc. The aircraft or spacecraft may have a propulsion system, such as an engine, rocket propulsion and/or braking and/or steering nozzles, or similar.

Summarizing and representing embodiments in other words, embodiments thus provide, among other things, a modular FPA. The flat monolithic FPA can be or can be divided into a modular system. Highly accurate positioning and/or thus simplified adjustment of the sensor can be made possible by a relatively easy-to-manufacture, for example planar (in the sense of planar in the surface on which the sensor/detector is fastened), FPA base body. Compensation of image field errors can be made possible by the targeted arrangement of the individual detectors in the array. Compensation options for color errors can be made possible through targeted arrangement of the individual color channels/spectral channels (e.g. z-tuning). Adjustment can be optimized by pre-mounting the FPA modules. Better space conditions for the use of adjusting means and/or a denser packing of the overall FPA can be realized. A heat flow gradient can be or be generated in the FPA for selective cooling or tempering by structurally different material thicknesses. Selective tempering of hotspots can be realized by spatial arrangement of the tempering devices. Selective tempering can be realized by correctly selecting the flow direction of the media/heat flow. The variants of selective tempering can be used and/or realized for both heat supply and cooling. The arrangement of the electronics can be realized along the surface of the FPA modules or in pockets of the FPA modules perpendicular to the focal plane. Short lines from the circuit board to the sensor module can be realized for optimal HF properties. An optimum connection to the thermal management system can be realized. Optimum accessibility for servicing, testing and commissioning can be realized on the individual module. A geometrically adapted circuit board with cavities for optimum local heating lines can be realized. Improved service and/or lower costs due to modular exchangeable units (e.g. color channels) with permanently attached components/sensors can be made possible. The FPA module can be designed from several components to optimize the thermal function. Embedding of materials or media (e.g. cooling channel) in the base body of the modular FPA for thermal optimization can be or can be implemented.

With embodiments, the image plane or focal plane can be reduced in size and/or utilized more efficiently. The integration density on the image plane or focal plane can be increased and/or the performance improved.

Example embodiments are described in more detail below with reference to figures, in which the following are shown schematically and by way of example:

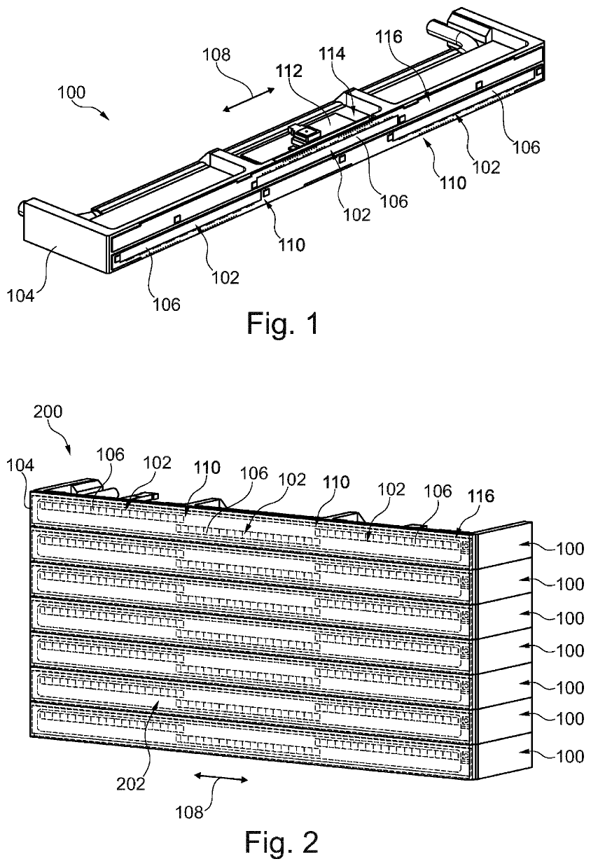

FIG. 1 shows a perspective view of a detector module in accordance with a variant;

FIG. 2 shows a perspective view of a combination of several detector modules in accordance with FIG. 1;

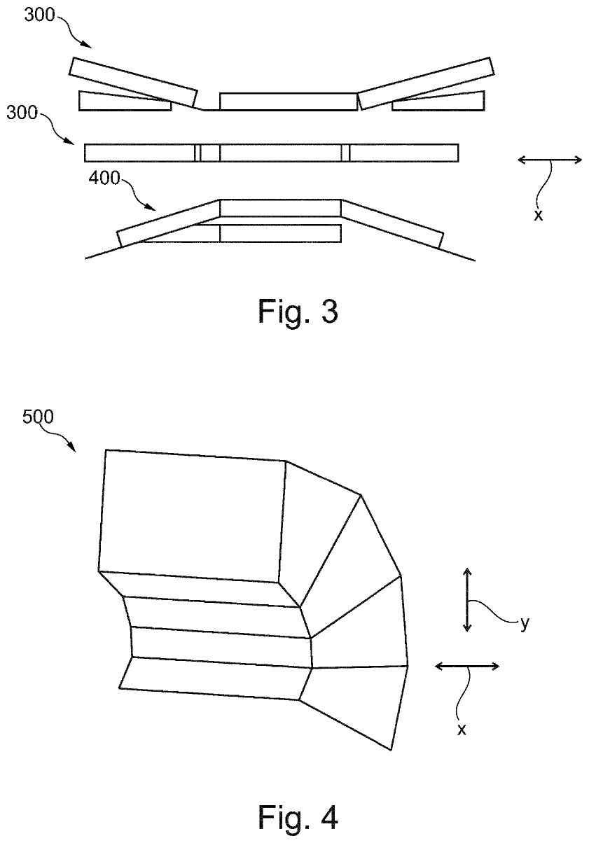

FIG. 3 shows schematic variants of detector modules;

FIG. 4 shows schematically a variant of a detector module;

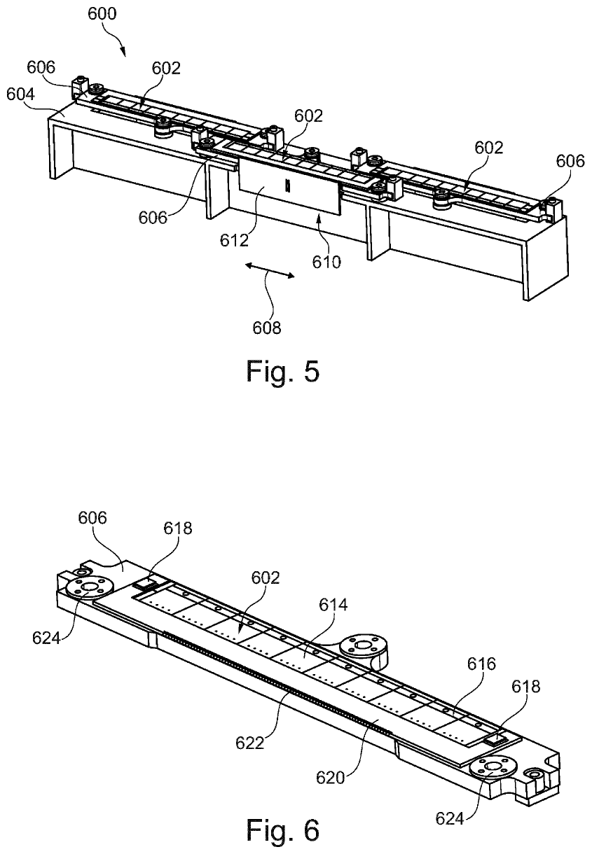

FIG. 5 shows a perspective view of a detector module in accordance with a further variant;

FIG. 6 shows a carrier plate with optoelectronic element of the detector module in accordance with FIG. 5;

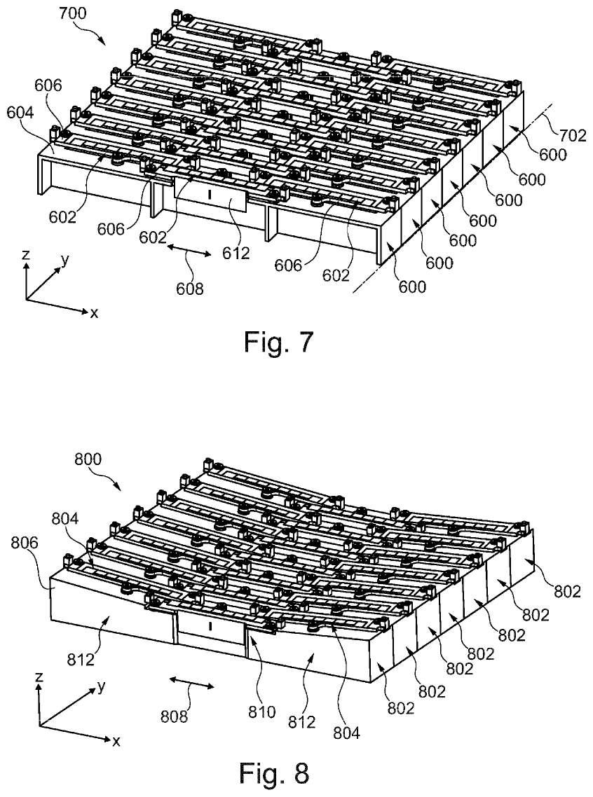

FIG. 7 shows a variant of a combination of several detector modules in accordance with FIG. 5;

FIG. 8 shows another variant of a combination of several detector modules;

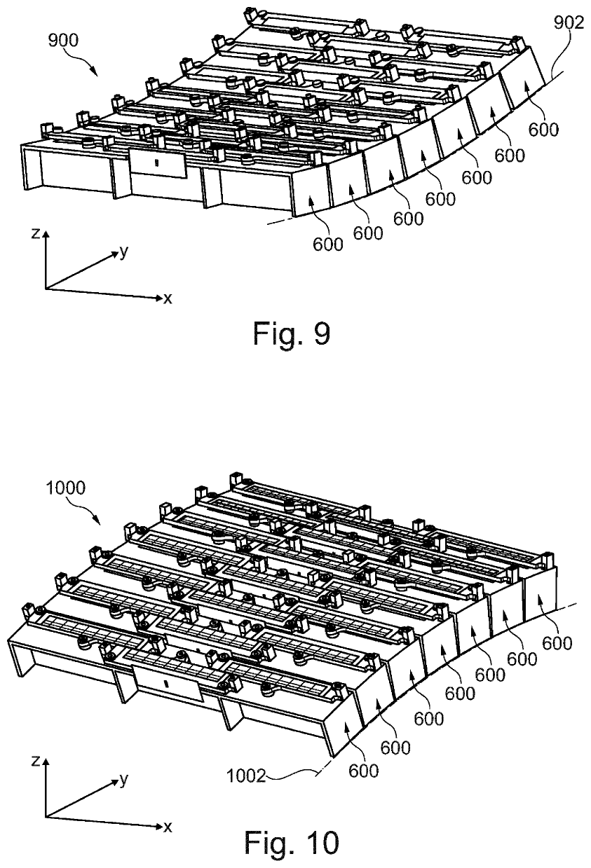

FIG. 9 shows another variant of a combination of several detector modules in accordance with FIG. 5;

FIG. 10 shows another variant of a combination of several detector modules in accordance with FIG. 5;

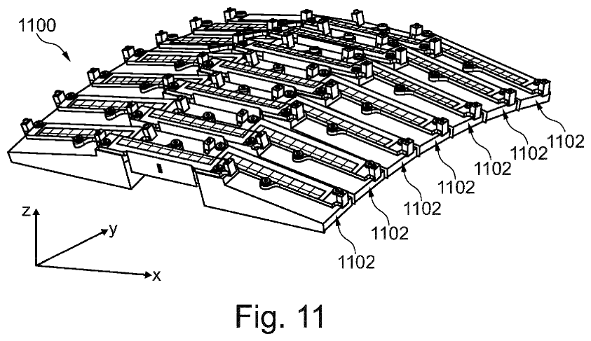

FIG. 11 shows another variant of a combination of several detector modules;

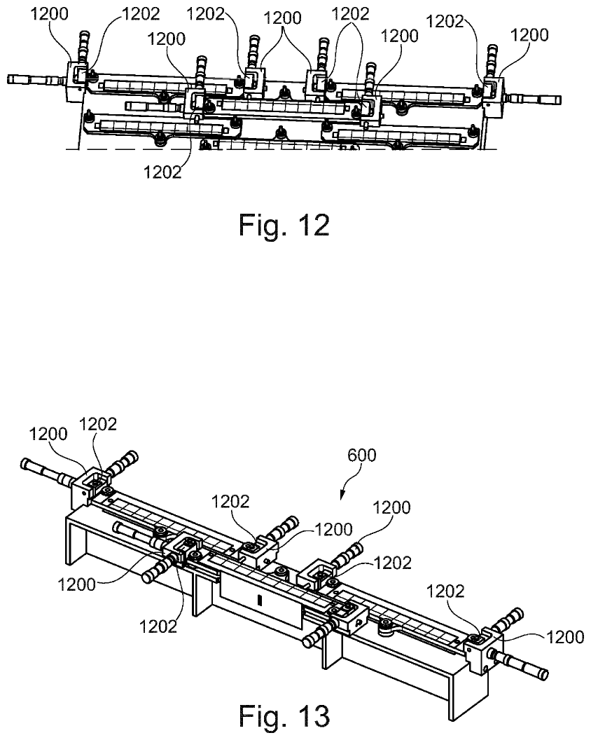

FIG. 12 shows the use of adjustment tools on a detector module;

FIG. 13 shows the detector module in accordance with FIG. 5 with adjustment tools;

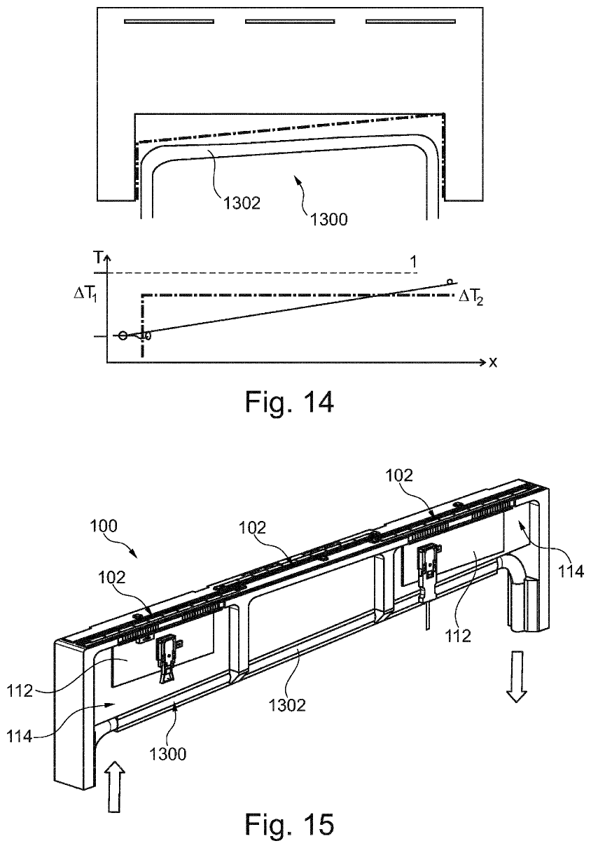

FIG. 14 shows an optimized heating line in a detector module;

FIG. 15 shows the detector module in accordance with FIG. 1 with a variant of a cooling and/or heating apparatus;

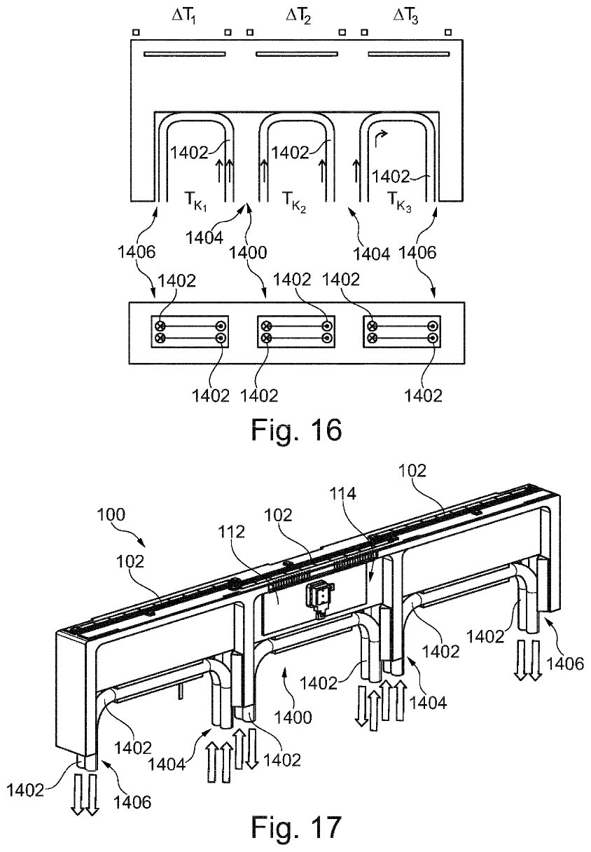

FIG. 16 shows a combination of media/heat flows in a detector module;

FIG. 17 shows the detector module in accordance with FIG. 1 with a further variant of a cooling and/or heating apparatus;

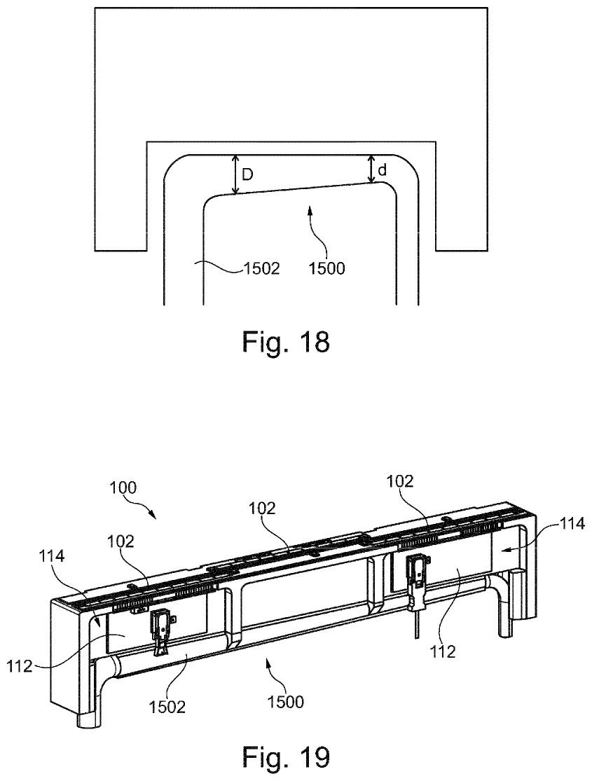

FIG. 18 shows selective cooling/tempering in a detector module;

FIG. 19 shows the detector module in accordance with FIG. 1 with a further variant of a cooling and/or heating apparatus;

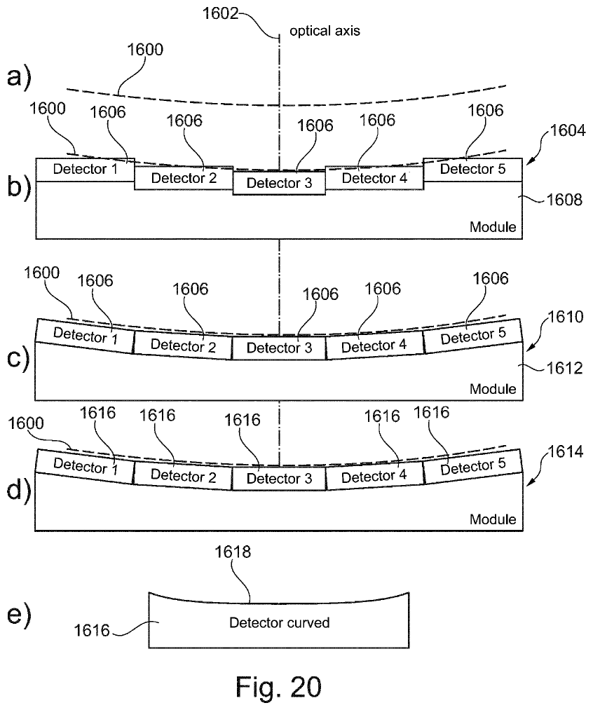

FIG. 20a shows schematically an optimal image field;

FIG. 20b shows schematically a variant of a detector module with a variant of an arrangement of optoelectronic elements;

FIG. 20c shows schematically a further variant of a detector module with a further variant of an arrangement of optoelectronic elements;

FIG. 20d shows schematically a further variant of a detector module with a further variant of an arrangement of optoelectronic elements;

FIG. 20e shows schematically a curved optoelectronic element;

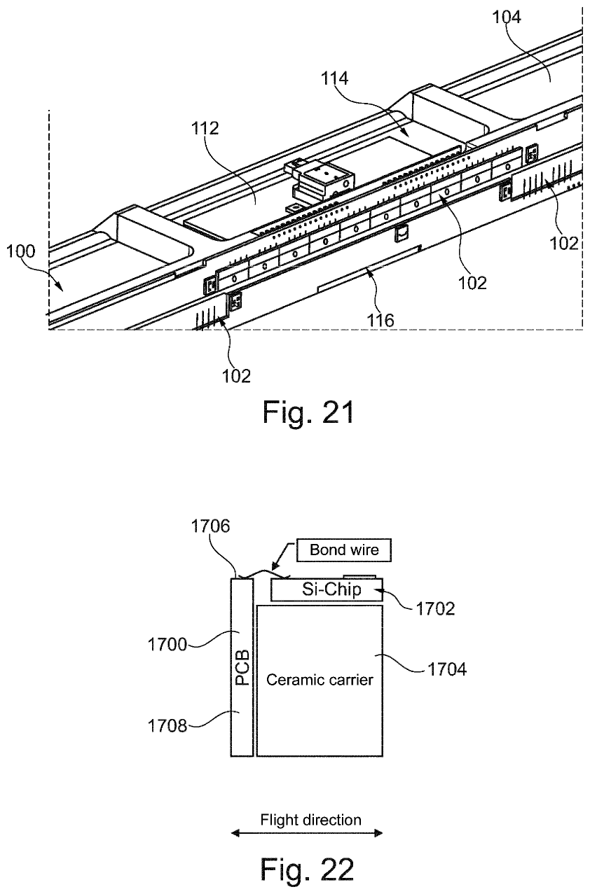

FIG. 21 shows an arrangement of a printed circuit board perpendicular to the focal plane in a detector module in accordance with FIG. 1;

FIG. 22 shows schematically a variant of an arrangement and connection of a printed circuit board to the optoelectronic element;

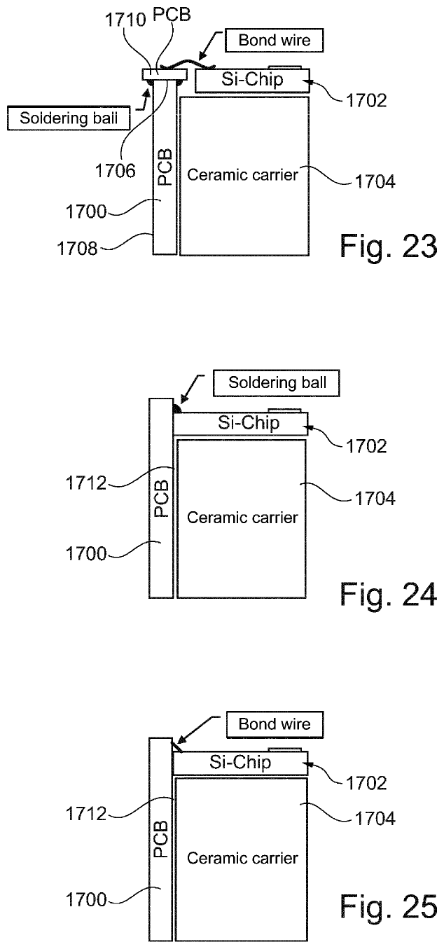

FIG. 23 shows schematically a further variant of an arrangement and connection of a printed circuit board to the optoelectronic element;

FIG. 24 shows schematically a further variant of an arrangement and connection of a printed circuit board to the optoelectronic element; and

FIG. 25 shows schematically a variant of an arrangement and connection of a printed circuit board to the optoelectronic element.

FIG. 1 schematically shows the structure of a basic module 100, such as detector module 100, for a modular FPA arrangement of an optoelectronic image capture system. The base module 100 can be the carrier for a color channel. In this embodiment, the sensors 102 (light-sensitive electronic chips and/or optoelectronic elements) are integrated directly into the detector module 100 and are not initially pre-assembled separately on chip carriers, such as carrier plates, and/or in separate housings.

The detector module 100 has a main module body 104 and at least one optoelectronic element 102 arranged on the main module body 104. In accordance with this embodiment according to FIG. 1, several, here three, optoelectronic elements 102 are directly integrated in the main module body 104. The optoelectronic elements 102 each have a line 106 with a plurality of pixels, such as pixel line 106. The optoelectronic elements 102 may be designed as detectors and/or light-sensitive sensor chips.

As shown in FIG. 1, the optoelectronic elements 102 are arranged substantially in a direction, such as longitudinal direction 108 of the detector module 100 or main module body 104, one behind the other. The optoelectronic elements 102 arranged one behind the other overlap in portions (as viewed in the transverse direction) in the longitudinal direction 108 of the detector module 100 or main module body 104 in their end areas 110, wherein the lines 106 with a plurality of pixels, such as pixel lines 106, of the plurality of optoelectronic elements 102 arranged one behind the other also overlap in portions in the longitudinal direction 108 of the detector module 100 or main module body 104 in their end areas 110, as viewed in the transverse direction. The detector module 100 is designed for at least one spectral channel.

FIG. 2 shows a detector module arrangement 200 with a combination of several basic modules 100, such as detector modules 100, arranged particularly next to one another, alongside the focal plane or which together define or form a total FPA or a common focal plane 202 or total image plane/image field 202. The combination of the base modules 100 or detector modules 100 may at least partially form the optoelectronic image capture system. The detector module arrangement 200 may form and/or be part of an optoelectronic image capture system.

FIG. 3 schematically shows a variant of an articulated front side of an FPA module or detector module 300 or 400 for a curved, substantially concave (shown at the top in FIG. 3, or convex (shown at the bottom in FIG. 3) image plane/image field transverse to the direction of flight. The detector module 300 or 400 in accordance with FIG. 3 can be designed in several parts for this purpose. FIG. 4 schematically shows wedge-shaped FPA modules or detector modules 500 for a curved image plane/image field in flight direction y.

Due to its modular design, the totality FPA offers the possibility of compensating for various imaging errors. In the case of a non-planar image field, the detectors 102 and/or their optoelectronic elements 102 can be or become inclined in the edge areas (cf. FIGS. 3, 8 and 11), so that a sharp image can always be guaranteed here. Convex and/or concave image field curvatures can be corrected. The compensation of spherical and/or aspherical image field curvatures can also be possible, at least approximately. Furthermore, the modular FPA can also offer the possibility of individually adjusting the effects of the longitudinal chromatic aberration of the imaging optics for the different spectral ranges.

The front of the individual module, such as detector module 300 or 400, can be divided along the direction transverse to the direction of flight (x-axis) (see FIG. 3). The main module body can be designed in several parts, wherein at least one part or each part of the main module body has at least one optoelectronic element. A wedge-shaped production/design (see FIG. 4) can be realized along the direction of flight (y-axis), particularly while maintaining the high manufacturing precision.

FIG. 5 shows a further variant of a detector module 600. The detector module 600 substantially corresponds to the detector module 100, but in the detector module 600, in contrast to the detector module 100, the optoelectronic elements 602 are arranged on the main module body 604, particularly by means of carrier plates 606. The main module body 604 is the carrier for the detectors 602 or optoelectronic elements 602 of a color channel/spectral channel. The carrier plates 606 are firmly connected to the main module body 604. The optoelectronic elements 602 are each fixedly arranged on a carrier plate 606 or may be integrated therein. The optoelectronic elements 602 are aligned in the longitudinal direction 608 by means of the carrier plate 606, particularly such that the end areas of the optoelectronic elements 602 overlap. In a receiving area 610, a printed circuit board 612 is arranged substantially perpendicular to the optoelectronic element 602. The circuit board may have an electrical circuit and/or be an electronic module that is electrically connected to the optoelectronic element 602.

FIG. 6 shows in detail a carrier plate 606 on the upper side of which an optoelectronic element 602 is arranged. The optoelectronic element 602 has a Si chip 614 comprising, for example, MCM of CMOS chip/detector and ROIC (read out integrated circuit). Further, the optoelectronic element 602 has an optical filter 616, such as spectral filters, electronic components 618, such as a clock or timer, for example a “high voltage clock” (HVCLK), a printed circuit board 620, for example PCT/LTCC, and/or electrically conductive contacts/contact points 622. The carrier plate 606 has mechanical interfaces 624 for adjustment and/or fixation. All optoelectronic elements 602 on a main module body 604 are aligned and/or fixed with respect to one another. The thermal connection and/or optimized tempering can be implemented at module level. Here, the detector module as a whole or optoelectronic elements 602 can be or can be individually temperature-controlled.

FIG. 7 shows a detector module arrangement 700 having a plurality of detector modules 600 in accordance with FIG. 5. The detector module arrangement 700 may form and/or be part of an optoelectronic image capture system. The combination of several detector modules 600 results in the totality FPA or the common image field. The detector modules 600 are arranged longitudinally directly next to each other and along a straight line 702 (which extends in the y-direction) and are connected to each other, so that the optoelectronic elements 602 of the detector modules 600 have or form a substantially planar image field and/or focal surface. The image field or the focal surface lies substantially in the plane spanned by the longitudinal direction/flight direction y and the lateral direction/transverse direction x. Each detector module 600 of the detector module arrangement 700 is designed for a spectral range. In FIG. 7, for example, the detector module arrangement 700 has seven detector modules 600 and can thus be designed for seven different spectral ranges or spectral channels.

FIG. 8 shows a detector module arrangement 800 with several detector modules 802. The detector module arrangement 800 may form and/or be part of an optoelectronic image capture system. The detector modules 802 substantially correspond to the detector modules 600 in accordance with FIG. 5, but have an articulated front side of the FPA module for a substantially concavely curved image plane/image field transverse to the direction of flight, i.e. in the x-direction. The image field can be flat along the longitudinal direction/flight direction y. The detector module arrangement 800 may thus have a concave image field curvature in the x-direction and a flat image field in the y-direction (direction of flight). The inclined position, of the outer optoelectronic elements 804 may be realized by an adapted main module body 806 or wedge-shaped plates, such as intermediate plates. The main module body 806 may be in one or more parts, for example in three parts. The main module body 806 is designed to be substantially wedge-shaped and/or angled in portions in the longitudinal direction 808 of the main module body 806. The main module body 806 may have a central portion 810 and two portions 812 angled with respect to the central portion 810, wherein each portion has an optoelectronic element 804. Alternatively, a substantially convex curvature can also be realized.

FIG. 9 shows a detector module arrangement 900 with several detector modules 600 in accordance with FIG. 5. The detector module arrangement 900 may form and/or be part of an optoelectronic image capture system. In contrast to the detector module arrangement 700, in the detector module arrangement 900 the detector modules 600 are arranged alongside each other, but along a curved line 902 (which extends substantially in the y-direction). The detector module arrangement 900 has a substantially concave curved image plane/image field in the longitudinal direction/direction of flight y or has a concave image field curvature in the y direction. Alternatively, the main module bodies 604 of the detector modules 600 can be designed to be correspondingly wedge-shaped, so that the concave curvature in the y-direction results from the longitudinal arrangement of the main module bodies or detector modules.

FIG. 10 shows a detector module arrangement 1000 with several detector modules 600 in accordance with FIG. 5. The detector module arrangement 1000 may form and/or be part of an optoelectronic image capture system. The detector module arrangement 1000 substantially corresponds to the detector module arrangement 900, but is designed to be substantially convex rather than concave. As represented in FIG. 10, the detector modules 600 are arranged alongside each other, but along a curved line 1002 (which extends substantially in the y-direction). The detector module arrangement 1000 has a convexly curved image plane/image field in the longitudinal direction/direction of flight y or has a convex image field curvature in the y direction. Alternatively, the main module bodies 604 of the detector modules 600 can be designed to be correspondingly wedge-shaped, so that the convex curvature in the y-direction results from the longitudinal arrangement of the main module bodies or detector modules.

FIG. 11 shows a detector module arrangement 1100 with several detector modules 1102. The detector module arrangement 1100 may form and/or be part of an optoelectronic image capture system. The detector module arrangement 1100 substantially corresponds to a combination of the detector module arrangement 800 and 1000, wherein the detector modules 1102 are designed and arranged in such a manner that a substantially convexly curved image plane/image field in the longitudinal direction/flight direction y and in the x-direction (transverse to the flight direction y/lateral direction) or a substantially convex image field curvature in the y-direction and x-direction is realized.

FIG. 12 shows the use of adjustment tools 1200 or adjustment devices 1202. The modular design of the FPA can offer the advantage of easier mounting and/or adjustment.

FIG. 13 shows the detector module 600 in accordance with FIG. 5 with adjustment tools 1200 and adjustment devices 1202. The individual detector modules 600 are freely accessible in the direction of flight y or perpendicular to the color channels/spectral channels. This accessibility can be used to utilize adjustment tools 1200 and/or adjustment devices 1202, particularly for the optoelectronic elements 602 (multi-chip mounts/sensors) and/or for the carrier plate 606 (chip carrier). After adjustment, the optoelectronic elements 602 or carrier plates 606 can be permanently fixed or realized. The adjustment tools 1200 and/or adjustment devices 1202 can then be removed. The detector modules 600 can then be set up very compactly to form a totality FPA in the y-axis.

The modular design of the FPA can offer the advantage of improved thermal management. The modular FPA can allow considerably more freedom for selective tempering. If a cooling device is used (e.g. passive or actively pumped cooling lines/heating lines/heat pipe), the cooling means may heat up. The cooling effect can therefore not be constant with homogeneous heat sources. There may be a temperature gradient between the left and right side of the detector module. This can lead to uneven heat distribution across the detector line.

FIG. 14 schematically shows an optimized heating line through modified material thicknesses. As shown schematically in FIG. 14, the base body or main module body of the modular FPA or the detector module can be geometrically designed in such a manner that a graduated temperature distribution can be achieved through different wall thicknesses and material thicknesses. This allows a homogeneous temperature distribution to be realized in the area of the detectors and/or the optoelectronic elements. This can have a positive effect on image quality.

FIG. 15 shows an example of a detector module 100 in accordance with FIG. 1 with a cooling apparatus and/or heating apparatus 1300 for cooling and/or heating the optoelectronic elements 102. In the present embodiment in accordance with FIG. 15, the cooling apparatus and/or heating apparatus 1300 has a cooling line and/or heating line for supplying a cooling means or heating means on one side of the detector module 100 (on the left in FIG. 15) and for discharging it on a side of the detector module 100 opposite this side (on the right in FIG. 15). In FIG. 15, the direction of flow of the cooling means or heating means is illustrated by the arrows. Further, the main module body 104 has different wall thicknesses and/or material thicknesses to form a graduated temperature distribution (in FIG. 15 larger/thicker on the left and smaller/thinner on the right). The cooling line and/or heating line 1302 thus has an inclined course (from left to right in FIG. 15). The temperature distribution at detector level can be and/or become optimized by an inclined cooling connection.

FIG. 16 shows a combination of media/heat flows. Hotspots in the FPA or in the detector module, caused by components with a high heat load, can be specifically tempered. This can be achieved by several individual cooling devices (e.g. heat pipes or heating lines), which are arranged geometrically, for example, in such a way that their position and/or the direction of flow of the cooling medium generate the highest cooling effect locally where hotspots are created by the components.

FIG. 17 shows an example of a detector module 100 in accordance with FIG. 1 with a cooling apparatus and/or heating apparatus 1400 for cooling and/or heating the optoelectronic elements 102, wherein the cooling apparatus and/or heating apparatus 1400 has a plurality of cooling lines and/or heating lines 1402. The cooling apparatus and/or heating apparatus 1400 and/or the cooling lines and/or heating lines are designed such that cooling means and/or heating means are supplied at a substantially interior and/or central location 1404 of the detector module 100 and are discharged at a side 1406, such as exterior side 1406, of the detector module 100. In this manner, individual cooling or heating of the individual optoelectronic elements 102 can be and/or can be realized. In particular, heat can be and/or is transported from the inside to the outside.

FIG. 18 shows selective cooling/tempering using modified media or heat flows. Hotspots in the FPA or in the detector module, caused by components with a high heat load, can further be specifically tempered by influencing the flow properties of the cooling medium. This can be achieved, for example, by adapting the cross-section of the temperature control device and/or cooling lines, which can change the flow rate of the medium. This allows targeted tempering of individual areas to be realized.

FIG. 19 shows an example of a detector module 100 in accordance with FIG. 1 with a cooling apparatus and/or heating apparatus 1500 for cooling and/or heating the optoelectronic elements 102, wherein the cooling line and/or heating line 1502 has a larger cross-section/line cross-section on one side of the detector module 100 (on the left in FIG. 19) than on a side opposite this side (on the right in FIG. 19) of the detector module 100. The cooling line and/or heating line 1502 can taper conically in the direction of flow or against the direction of flow of the cooling means and/or heating means, at least in portions. In this manner, different heat transport can be or can be realized.

Additionally or alternatively, thermal hotspots can be specifically decoupled from thermally sensitive components (e.g. detector or optoelectronic elements). For this purpose, the heating lines in regions of the FPA modules or detector modules can be or are specifically modified by geometric design (e.g. air gap) or corresponding material selection (e.g. materials with particularly good or poor thermal conductivity).

FIG. 20a schematically shows an optimal image field, here of a spherical and/or convex image field, with respect to an optical axis 1602. FIG. 20b schematically shows a variant of a detector module 1604 with a variant of an arrangement of optoelectronic elements or detectors 1606, wherein a step-shaped main module body 1608 is provided and the individual optoelectronic elements or detectors 1606 are each arranged on a step. This allows a modular FPA to be realized with a stepped adjustment, substantially approximating the optimal image field. FIG. 20c schematically shows a further variant of a detector module 1610 with a further variant of an arrangement of optoelectronic elements or detectors 1606, wherein the main module body 1612 has portions angled towards each other instead of steps, on each of which an optoelectronic element or detector 1606 is arranged. Hereby, a modular FPA with oblique optoelectronic elements or detectors 1606 with substantially wedge-shaped adaptation to the optimal image field and thus a better approximation can be realized. FIG. 20d schematically shows a further variant of a detector module 1614 with a further variant of an arrangement of curved optoelectronic elements or detectors 1616, each of which has a curved surface 1618, such as sensor surface. Such a curved optoelectronic element or detector 1616 is shown schematically in FIG. 20e. This makes it possible to realize a modular FPA with curved optoelectronic elements or detectors 1616 and thus a substantially ideal adaptation to the optimal image field.

FIG. 12 shows an arrangement of a printed circuit board 112 of the detector module 100 in accordance with FIG. 1 perpendicular to the focal plane. The modular FPA or detector module 100 can realize an arrangement of the circuit boards 112 in the third dimension (e.g., perpendicular to the actual focal plane). Due to the structural design with recesses and/or pockets 114, the printed circuit boards 112 can be fixed in a stable manner, particularly in these recesses and/or pockets 114, but can remain freely accessible for maintenance of the individual module. Since one edge of the circuit board 112 may extend directly on the back of the detector 102/multi-chip module 102, very short line paths may be realized, which may be better suited for high frequency signals. The circuit boards 112 themselves may be arranged along the FPA module surface/detector module surface and/or in pockets and/or recesses 114 and/or may also be or become efficiently integrated into the thermal concept. The circuit boards 112 may have an electronic circuit. As an alternative to the printed circuit boards 112, an electronic circuit and/or an electronic module may be arranged accordingly. The main module body 104 may have a carrier surface 116 on which the optoelectronic elements 102 are arranged. The main module body 104 may have a plurality of portions designed substantially perpendicular to the carrier surface 116, which are designed to receive at least one electronic circuit, such as signal processing and/or readout circuit, and/or to receive at least one printed circuit board 112. The portions each have a receiving area 114, in particular a recess and/or pocket 114, in which the at least one electronic circuit and/or printed circuit board 112 is arranged and/or can be arranged. The at least one electronic circuit and/or printed circuit board 112 is electrically connected to a respective optoelectronic element 102.

For a thermally optimized connection, the sensor or the optoelectronic element 102 can generally be or become permanently fixed to the FPA or the detector module 100, for example by adhesive bonding. With this connection, which cannot be released non-destructively, it may be important to be able to exchange the sensors 102 and/or the detector modules 100 in small units in the service case, e.g. as one color channel. This can be made possible by the modular FPA concept.

FIG. 22 schematically shows a variant of an arrangement and connection of a printed circuit board 1700 to or with an optoelectronic element 1702, which is arranged on a main module body 1704. As represented in FIG. 22, the printed circuit board 1700 is arranged substantially perpendicular to the optoelectronic element 1702 and is electrically connected to the optoelectronic element 1702 by means of bonding, such as wire ground, or a bond connection. The electrical connection is realized via a face side and/or side surface 1706 of the printed circuit board 1700. For this purpose, the face side 1706 of the printed circuit board 1700 can have at least one electrically conductive contact point, which is electrically connected to at least one electrically conductive contact point of the optoelectronic element 1702. The printed circuit board 1700 may have conductive tracks extending transversely and/or substantially perpendicular to each other, wherein at least one conductive track extends substantially parallel to the face side 1706 of the printed circuit board 1700 and at least one further conductive track extends substantially parallel to a side surface 1708 extending substantially perpendicular to the face side 1706.

FIG. 22 therefore illustrates a possible arrangement of an additional printed circuit board 1700 to a printed circuit board of the sensor chip/optoelectronic element 1702 or to a sensor chip/optoelectronic element 1702 to be contacted directly at an angle, in the present exemplary embodiment of 90°. A wire bond from the face side 1706 of the printed circuit board 1700 to the other printed circuit board or directly to the sensor chip/optoelectronic element 1702, for example a wire bond from chip pad to edge pad, enables a space-optimized variant or design. In the interest of optimum image quality, the sensor or detector module can be designed to be as compact as possible in the direction of flight, particularly if several sensors or detector modules are combined in one system.

FIG. 23 schematically shows a further variant of an arrangement and connection of the printed circuit board 1700 to or with the optoelectronic element 1702. In accordance with this variant, a further printed circuit board 1710 is arranged on the face side 1706 of the printed circuit board 1700, which is substantially perpendicular to the printed circuit board 1700 and is electrically connected to the optoelectronic element 1702 by means of wire bonding, particularly via an electrically conductive contact point. This allows indirect edge contacting to be realized. The printed circuit board 1700 is electrically connected to the further printed circuit board 1710, for example by means of soldering, such as solder jet bumping.

FIG. 24 schematically shows a further variant of an arrangement and connection of the printed circuit board 1700 to or with the optoelectronic element 1702. In accordance with this variant, the printed circuit board 1700 is electrically connected to the optoelectronic element 1702 via a side surface 1712 facing the optoelectronic element 1702, here for example by means of soldering, such as solder jet bumping. In this manner, 90° contacting can be realized, particularly by means of soldering technology.

FIG. 25 schematically shows a further variant of an arrangement and connection of the printed circuit board 1700 to or with the optoelectronic element 1702. In accordance with this variant, the printed circuit board 1700 is electrically connected to the optoelectronic element 1702 via a side surface 1712 facing the optoelectronic element 1702, here for example by means of a base, such as wire bonding. In this manner, a 90° contact can be realized, particularly by means of a bond connection.

“May” refers in particular to optional features of embodiments. Accordingly, there are also developments and/or example embodiments which additionally or alternatively have the respective feature or the respective features.

From the feature combinations disclosed in herein, isolated features may also be singled out as required and, by resolving an optionally existing structural and/or functional relationship between the features in combination with other features, be used to delimit the subject matter of the claim.

### REFERENCE SIGNS

100 detector module
102 optoelectronic elements
104 main module body
106 pixel lines
108 longitudinal direction
110 end areas
112 electronic circuit/printed circuit board
114 recesses/pockets
116 carrier surface
200 detector module arrangement
202 common focal plane/image plane/image field
300 detector module
400 detector module
500 detector module
600 detector module
602 optoelectronic elements
604 main module body
606 carrier plates
608 longitudinal direction
610 receiving area
612 printed circuit board
614 Si chip/CMOS, ROIC
616 optical filter
618 electronic components/HVCLK
620 printed circuit board
622 electrically conductive contacts/contact points
624 mechanical interfaces
700 detector module arrangement
702 straight line
800 detector module arrangement
802 detector modules
804 optoelectronic elements
806 main module body
808 longitudinal direction
810 central portion
812 angled portions
900 detector module arrangement
902 curved line (concave)
1000 detector module arrangement
1002 curved line (convex)
1100 detector module arrangement
1102 detector modules
1200 adjustment tools
1202 adjustment devices
1300 cooling apparatus and/or heating apparatus
1302 cooling line and/or heating line
1400 cooling apparatus and/or heating apparatus
1402 cooling lines and/or heating lines
1404 inside and/or centered location
1406 exterior side
1500 cooling apparatus and/or heating apparatus
1502 cooling line and/or heating line
1600 image field
1602 optical axis
1604 detector module
1606 optoelectronic elements or detectors
1608 main module body
1610 detector module
1612 main module body
1614 detector module
1616 optoelectronic elements or detectors
1618 curved surface/sensor surface
1700 printed circuit board
1702 optoelectronic element
1704 main module body
1706 face side
1708 side surface
1710 further printed circuit board
1712 side surface
y flight direction/image capture direction/longitudinal direction of the aircraft
x direction transverse to the flight direction or image capture direction/lateral direction of the aircraft
z vertical axis/height direction of the aircraft
D/d diameter/line cross-section

1. A detector module for image capture, particularly for an optoelectronic image capture system for an aircraft, comprising a main module body and at least one optoelectronic element arranged on and/or integrated in the main module body, wherein the at least one optoelectronic element has at least one line with a plurality of pixels, such as a pixel line.

2. The detector module according to claim 1, wherein the detector module comprises a plurality of optoelectronic elements arranged and/or integrated, particularly directly, on the main module body, such as detectors and/or light-sensitive sensor chips, which are arranged substantially in a direction, such as longitudinal direction of the detector module or main module body, one behind the other.

3. The detector module according to claim 2, wherein the optoelectronic elements arranged one behind the other overlap in portions, in particular in one direction, such as the longitudinal direction of the detector module or main module body, and/or in their end areas, particularly when viewed in the transverse direction, and/or in that the lines with a plurality of pixels, such as pixel lines, of the optoelectronic elements arranged one behind the other extend in portions, particularly in a direction such as the longitudinal direction of the detector module or main module body, and/or overlap in their end areas, particularly when viewed in the transverse direction.

4. The detector module according to claim 2, wherein the optoelectronic elements arranged one behind the other, particularly in a direction such as the longitudinal direction of the detector module or main module body, are arranged directly adjacent to or spaced apart from one another.

5. The detector module according to claim 1, wherein the detector module is designed for at least one spectral channel.

6. The detector module according to claim 1, wherein the at least one optoelectronic element is connected to the main module body.

7. The detector module according to claim 1, wherein the main module body is designed in several parts, wherein at least one part or each part of the main module body has at least one optoelectronic element.

8. The detector module according to claim 1, wherein the main module body, particularly in the longitudinal direction and/or in the transverse direction of the main module body, is designed to be substantially arcuate and/or wedge-shaped and/or angled and/or stepped, at least in portions.

9. The detector module according to claim 1, wherein the main module body comprises a central portion and at least one portion angled or stepped with respect to the central portion, wherein at least one or each portion has at least one optoelectronic element.

10. The detector module according to claim 1, wherein the at least one optoelectronic element, in particular in the longitudinal direction and/or in the transverse direction of the at least one optoelectronic element, is designed substantially wedge-shaped and/or step-shaped and/or angled and/or arcuate, in particular curved, at least in portions.

11. The detector module according to claim 1, wherein the detector module, particularly the at least one or the optoelectronic elements of the detector module, have and/or form a substantially planar, concave, convex or spherical image field and/or focal surface.

12. The detector module according to claim 1, wherein the main module body has a carrier surface on which the at least one optoelectronic element and/or the plurality of optoelectronic elements are arranged.

13. The detector module according to claim 12, wherein the main module body has at least one portion which is designed substantially perpendicular to the carrier surface and which is designed to receive at least one electronic circuit, such as a signal processing and/or readout circuit, and/or to receive at least one printed circuit board.

14. The detector module according to claim 13, wherein the at least one portion has at least one receiving area, in particular a recess and/or pocket, in which the at least one electronic circuit and/or printed circuit board can be arranged.

15. The detector module according to claim 13, wherein the detector module has the at least one electronic circuit and/or printed circuit board which is connected, particularly electrically, to the at least one optoelectronic element.

16. The detector module according to claim 13, wherein the at least one electronic circuit and/or printed circuit board can be arranged on and/or is arranged at an angle, particularly transversely and/or substantially perpendicularly, to the carrier surface and/or to the at least one optoelectronic element.

17. The detector module according to claim 15, wherein the at least any electronic circuit and/or printed circuit board is connected to the at least one optoelectronic element by means of bonding, such as wire base, or a bond connection, and/or by means of soldering, such as solder jet bumping, or a solder connection, and/or by means of welding, such as laser welding, or a welding connection.

18. The detector module according to claim 15, wherein the electrical connection is made or implemented via a face side and/or side surface of the at least one printed circuit board.

19. The detector module according to claim 15, wherein a face side of the at least one printed circuit board has at least one electrically conductive contact point which is electrically connected to at least one electrically conductive contact point of the at least one optoelectronic element.

20. The detector module according to claim 15, wherein the at least one printed circuit board has conductive tracks extending transversely and/or substantially perpendicularly to one another, wherein at least one conductive track extends substantially parallel to a face side of the at least one printed circuit board and at least one further conductive track extends substantially parallel to a side surface extending substantially perpendicular to the face side.

21. The detector module according to claim 15, wherein on one face side of the at least one printed circuit board at least one further printed circuit board is arranged substantially perpendicular to the printed circuit board, which is electrically connected, particularly via an electrically conductive contact point, to the at least one optoelectronic element.

22. The detector module according to claim 21, wherein the at least one printed circuit board is electrically connected to the further printed circuit board, particularly by means of bonding, such as wire bonding, and/or by means of soldering, such as solder jet bumping, and/or by means of welding, such as laser welding.

23. The detector module according to claim 1, wherein the at least one optoelectronic element is an optoelectronic detector and/or a light-sensitive sensor chip.

24. The detector module according to claim 1, wherein the at least one optoelectronic element comprises at least one, particularly rigid or flexible, printed circuit board, at least one line-shaped light-sensitive chip, such as CMOS chip, and/or at least one integrated signal processing and/or readout circuit.

25. The detector module according to claim 1, wherein the detector module has at least one cooling apparatus and/or heating apparatus arranged on and/or designed for the main module body, particularly for cooling and/or heating the at least one optoelectronic element.

26. The detector module according to claim 1, wherein the main module body has different wall thicknesses and/or material thicknesses for forming a graded temperature distribution.

27. The detector module according to claim 1, wherein the detector module has at least one cooling line and/or heating line for targeted cooling and/or heating.

28. The detector module according to claim 25, wherein the at least one cooling apparatus and/or heating apparatus and/or the at least one cooling line and/or heating line is/are designed to supply cooling means or heating means on one side of the detector module and to discharge them on a side of the detector module opposite this side.

29. The detector module according to claim 25, wherein the at least one cooling apparatus and/or heating apparatus and/or the at least one cooling line and/or heating line is/are designed to supply cooling means and/or heating means at a substantially internal and/or central location of the detector module and to discharge them at a side, such as the exterior side, of the detector module.

30. The detector module according to claim 27, wherein the at least one cooling line and/or heating line is/are designed to influence and/or change the flow properties of a cooling means and/or heating means, particularly by means of adapted cross-sections, such as line cross-sections.

31. The detector module according to claim 30, wherein the at least one cooling line and/or heating line on one side of the detector module has a larger cross-section than on a side of the detector module opposite this side.

32. The detector module according to claim 30, wherein the at least one cooling line and/or heating line tapers conically at least in portions in the direction of flow or counter to the direction of flow of the cooling means and/or heating means.

33. The detector module according to claim 1, wherein the main module body is produced at least in portions from materials which have different thermal conductivities and/or thermal conductivity coefficients in order to form different temperature distributions.

34. An optoelectronic image capture system for an aircraft, particularly a spacecraft, comprising at least one detector module or a plurality of detector modules according to claim 1.

35. The optoelectronic image capture system according to claim 34, further comprising a modular image field arrangement and/or focal plane arrangement.

36. The optoelectronic image capture system according to claim 34, wherein the plurality of detector modules, particularly the optoelectronic elements of the detector modules, form a common image field and/or focal area.

37. The optoelectronic image capture system according to claim 34, wherein the plurality of detector modules are arranged next to one another and/or connected to one another, particularly directly and/or longitudinally.

38. The optoelectronic image capture system according to claim 34, wherein the plurality of detector modules are arranged along a straight line or curved line.

39. The optoelectronic image capture system according to claim 34, wherein the common image field and/or focal surface is substantially curved, in particular convex or concave or spherically curved, particularly in the image capture direction and/or flight direction of the aircraft and/or transverse, such as substantially perpendicular, to the image capture direction and/or flight direction of the aircraft.

40. The optoelectronic image capture system according to claim 34, wherein the optoelectronic image capture system has an optical system focusing on at least one detector module, particularly on at least one optoelectronic element, and/or on the image field and/or focal surface.

41. An aircraft, particularly a spacecraft, comprising at least one detector module according to claim 1.
